(19) United States
(12) Patent Application Publication
(10) Pub. No.: US 2026/0221944 A1
(43) Pub. Date: Jul. 30, 2026

(54) THREE-DIMENSIONAL RADIO FREQUENCY MODULE SYSTEM-IN-PACKAGE STRUCTURE

(71) Applicant: SJ Semiconductor(Jiangyin) Corporation, Jiangyin (CN)

(72) Inventors: Yenheng CHEN, Jiangyin (CN); Chengchung LIN, Jiangyin (CN)

(73) Assignee: SJ Semiconductor(Jiangyin) Corporation, Jiangyin, JS (CN)

(21) Appl. No.: 19/143,925

(22) PCT Filed: Oct. 27, 2023
(86) PCT No.: PCT/CN2023/127215

§ 371 Date: Jun. 27, 2025

(30) Foreign Application Priority Data
Dec. 29, 2022 (CN) 202223545640.X

(51) Int. Cl. H03F 1/26; H03F 3/24

(52) U.S. Cl. CPC H03F 1/26; H03F 3/245; H03F 2200/114; H03F 2200/294; H03F 2200/451

(57) ABSTRACT

A SIP structure of three-dimensional RF module, which integrates various RF components into a SIP structure of the three-dimensional RF module including the first rewiring layer, the second rewiring layer, and the metal columns, which can realize a high-performance systematic packaging, and the packaging line dimension and line space dimension can be down to 2 μm/2 μm, which can effectively reduce the packaging area and packaging volume.

### FIELD OF TECHNOLOGY

The present disclosure model relates to semiconductor technology, in particular, to a three-dimensional radio frequency (RF) module in a system-in-package (SIP) Structure.

### BACKGROUND

A wireless system generally contains four parts: an antenna, an RF front end, an RF transceiver module, and a baseband signal processor. With the arrival of the 5G era, the demand and value of the antenna and the RF front-end have been rising rapidly. The RF front-end is a basic component that converts digital signals to wireless RF signals, and is also a core component of the wireless communication system.

At present, the mainstream packaging method for RF modules entails the Flip-Chip-on-Substrate process. This technique employs the inverted attachment of individual chips onto a flat substrate for electrical connections, thereby obtaining a SIP structure. However, the resulting structure has a relatively large package size, imposing limitations on the design of end products.

Therefore, providing a three-dimensional RF module SIP structure is necessary.

### SUMMARY

The present disclosure provides a three-dimensional RF module in a SIP structure enabling large packaging dimensions in RF module SIP technology.

The SIP structure of a three-dimensional RF module comprises:
a first rewiring layer, wherein the first rewiring layer comprises a first surface and a second surface opposite to the first surface;
metal columns, wherein the metal columns are located on the first surface of the first rewiring layer and the first end portions of the metal columns are electrically connected to the first rewiring layer;
an RF switch and a duplexer, wherein both the RF switch and the duplexer are located on the first surface of the first rewiring layer, and electrically conductive connectors of both the RF switch and the duplexer are located on the side away from the first rewiring layer;
a first packaging layer, wherein the first packaging layer is located on the first surface of the first rewiring layer and it embeds the metal columns, the RF switch, and the duplexer, but exposes the second end portions of the metal columns, as well as the electrically conductive connectors of both the RF switch and the duplexer;
a second rewiring layer, wherein the second rewiring layer is located on the first packaging layer and comprises a first surface in contact with the first packaging layer and a second surface opposite to its first surface, the second rewiring layer is electrically connected to the second end portions of the metal columns, and the second rewiring layer is electrically connected to the electrically conductive connectors of both the RF switch and the duplexer;
a low noise amplifier, a power amplifier, and a filter, wherein the low noise amplifier, the power amplifier and the filter are located on the second surface of the second rewiring layer, and the electrically conductive connectors of the low noise amplifier, the power amplifier and the filter are electrically connected to the second rewiring layer; and
a first bottom filling layer, wherein the first bottom filling layer is located on the second surface of the second rewiring layer and it covers the electrically conductive connectors of the low noise amplifier, the power amplifier, and the filter.

Optionally, the SIP structure of the three-dimensional RF module further comprises a second packaging layer located on the second surface of the second rewiring layer, covering the low noise amplifier, the power amplifier, the filter and the first bottom filler layer.

Optionally, the SIP structure of the three-dimensional RF module further comprises a second packaging layer located on the second surface of the second rewiring layer, covering the low noise amplifier, the power amplifier, the filter and the first bottom filler layer.

Optionally, the SIP structure of the three-dimensional RF module further comprises a PCB substrate and a transceiver, the transceiver and an intermediate packaging structure comprising the electromagnetic isolation protective housing are electrically connected to the PCB substrate.

Optionally, the SIP structure of the three-dimensional RF module further comprises a transceiver located on the second surface of the first rewiring layer and electrically connected to the first rewiring layer via conductive pads, wherein a second bottom filling layer is disposed in between the transceiver, pads, and the second surface of the first rewiring layer.

Optionally, the SIP structure of the three-dimensional RF module further comprises metal bumps located on the second surface of the first rewiring layer and electrically connected to the first rewiring layer, and the end portions of the metal bumps are further intruding away from the first rewiring layer than the bottom surface of the transceiver is from the first rewiring layer.

Optionally, the SIP structure of the three-dimensional RF module further comprises a third packaging layer covering the transceiver, the second bottom filling layer, pad, and the metal bumps, wherein the first surface of the third packaging layer is in contact with the second surface of the first rewiring layer, and the second surface of the third packaging layer exposes the end portions of the metal bumps.

Optionally, the SIP structure of the three-dimensional RF module further comprises an electromagnetic isolation protective housing, which exposes the second surface of the third packaging layer, and is disposed at a periphery of the first packaging layer, the second packaging layer, the third packaging layer, the first rewiring layer, and the second rewiring layer.

Optionally, a line dimension of the SIP structure of the three-dimensional RF module is 2 μm or less, and a line space dimension of the SIP structure of the three-dimensional RF module is 2 μm or less.

Optionally, the SIP structure of the three-dimensional RF module is a wafer-level SIP structure of the three-dimensional RF module.

As described above, the presently disclosed SIP structure of the three-dimensional RF module integrates various RF components into a SIP structure of the three-dimensional RF module through the first rewiring layer, the second rewiring layer, and the metal columns, which can realize a high-performance SIP structure, and the packaging line dimension/spacing can be as small as 2 μm/2 μm, which can effectively reduce the packaging area and packaging volume.

### BRIEF DESCRIPTION OF THE DRAWINGS

FIG. 1 shows a schematic structural diagram of a SIP structure of the three-dimensional RF module according to Embodiment 1 of the present disclosure.

FIG. 2 shows a schematic structural diagram of a SIP structure of the three-dimensional RF module, according to Embodiment 2 of the present disclosure.

FIG. 3 shows a schematic structural diagram of a SIP structure of the three-dimensional RF module according to Embodiment 3 of the present disclosure.

FIG. 4 shows a schematic structural diagram of a SIP structure of the three-dimensional RF module according to Embodiment 4 of the present disclosure.

FIG. 5 shows a schematic structural diagram of a SIP structure of the three-dimensional RF module according to Embodiment 5 of the present disclosure.

FIG. 6 shows a schematic structural diagram of a SIP structure of the three-dimensional RF module according to Embodiment 6 of the present disclosure.

FIG. 7 shows a schematic structural diagram of a SIP structure of the three-dimensional RF module according to Embodiment 7 of the present disclosure.

### REFERENCE NUMERALS

110 First rewiring layer
111 First metal wiring layer
112 First dielectric layer
120 Second rewiring layer
121 Second metal wiring Layer
122 Second dielectric layer
200 Metal columns
301 RF switch
302 Duplexer
303 Low noise amplifier
304 Power amplifier
305 Filter
306 Transceiver
410 First packaging layer
420 Second packaging layer
430 Third packaging layer
501 First bottom filling layer
502 Second bottom filling layer
600 Electromagnetic isolation protective housing
700 Metal bumps
800 PCB Substrate

### DETAILED DESCRIPTION

The embodiments of the present disclosure will be described below. Those skilled can easily understand disclosure advantages and effects of the present disclosure according to contents disclosed by the specification. The present disclosure can also be implemented or applied through other different specific embodiments. Various details in this specification can also be modified or changed based on different viewpoints and applications without departing from the spirit of the present disclosure.

When describing the embodiments of the present disclosure, for better explanation, cross-sectional structural diagrams may be partially enlarged without following the general scale. Moreover, the diagrams are only examples and should not limit the scope of the present disclosure. In addition, the actual production should comprise the length, width and depth of the three-dimensional space dimensions.

For the convenience of description, spatial relation terms such as “below”, “under”, “beneath”, “on”, “above”, “up”, etc. may be used herein to describe the relationships between an element or feature and other elements or features. It will be understood that these spatial relationship terms are intended to encompass directions/orientations of the device in use or operation other than those depicted in the drawings. In addition, when a first layer is referred to as being “between” a second layer and a third layer, the first layer may be the only layer between the second and third layers, or there may more layers between the two layers. Herein, “between . . . ” are used to include both endpoints.

In the context of this disclosure, the structure described with a first feature “on top” of a second feature may include embodiments where the first and second features are formed in direct contact, or it may include embodiments where additional features are formed between the first and second features such that the first and second features are not in direct contact.

It should be noted that the drawings provided in this disclosure only illustrate the basic concept of the present disclosure in a schematic way, so the drawings only show the components closely related to the present disclosure. The drawings are not necessarily drawn according to the number, shape and size of the components in actual implementation; during the actual implementation, the type, quantity and proportion of each component can be changed as needed, and the components'layout may also be more complicated.

### Embodiment 1

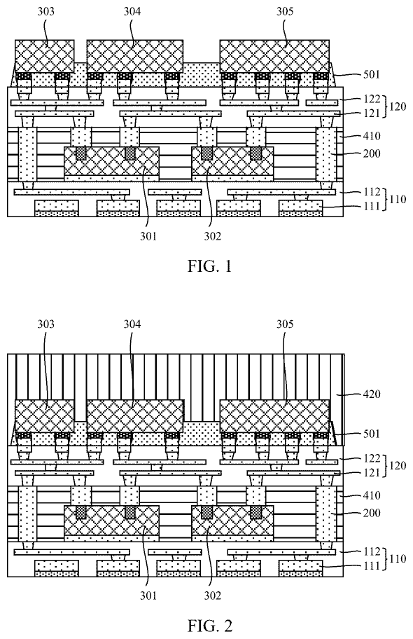

As shown in FIG. 1, Embodiment 1 provides a SIP structure of the three-dimensional RF module, which comprises: a first rewiring layer 110, metal columns 200, an RF switch 301, a duplexer 302, a first packaging layer 410, a second rewiring layer 120, a low-noise amplifier 303, a power amplifier 304, a filter 305, and a first bottom filling layer 501.

Specifically, the first rewiring layer 110 has a first surface and a second surface opposite to the first surface; the metal columns 200 are located over the first surface of the first rewiring layer 110 and first end portions of the metal columns 200 are electrically connected to the first rewiring layer 110; both the RF switch 301 and the duplexer 302 are located on the first surface of the first rewiring layer 110, and electrically conductive connectors of both the RF switch 301 and the duplexer 302 are further away from the first rewiring layer 110; the first packaging layer 410 is located on the first surface of the first rewiring layer 110 covering the metal columns 200, the RF switch 301 and the duplexer 302, and it exposes the second end portions of the metal columns 200, and the electrically conductive connectors of both the RF switch 301 and the duplexer 302; the second rewiring layer 120 is located on the first packaging layer 410 and has a first surface in contact with the first packaging layer 410 and a second surface opposite to its first surface, the second rewiring layer 120 is electrically connected to the second end portions of the metal columns 200, and the second rewiring layer 120 is electrically connected to the electrically conductive connectors of both the RF switch 301 and the duplexer 302; the low noise amplifier 303, the power amplifier 304 and the filter 305, wherein the low noise amplifier 303, the power amplifier 304 and the filter 305 are located on the second surface of the second rewiring layer 120 and electrically conductive connectors of the low noise amplifier 303, the power amplifier 304 and the filter 305 are electrically connected to the second rewiring layer 120; and the first bottom filling layer 501 is located on the second surface of the second rewiring layer 120 and covering the electrically conductive connectors of the low noise amplifier 303, the power amplifier 304 and the filter 305.

Specifically, the first rewiring layer 110 includes a first dielectric layer 112 and a metal wiring layer 111 located in the first dielectric layer 112, the second rewiring layer 120 includes a second dielectric layer 112 and a second metal wiring layer 121, located in the second dielectric layer 122, the first metal wiring layer 111 located in the first rewiring layer 110 may be an N-layer structure, wherein N≥1, such as 1, 2, 3, 5, etc. The second metal wiring layer 121 located in the second rewiring layer 120 may be an M-layer structure, wherein M≥1, such 1, 2, 3, 5, etc.

The metal columns 200 are made of one or more of copper, and nickel; the electrically conductive connectors of the RF switch 301, the duplexer 302, the low noise amplifier 303, the power amplifier 304, the filter 305 can be solder bumps, metal columns, or solder bumps (not shown) located above metal columns. They may also be metal pads and a solder layer (not shown) covering the metal pads.

The method of forming the first packaging layer 410 comprises one of compression molding, transfer molding, liquid seal molding, vacuum laminating, and spin coating; after forming the first packaging layer 410, the method may also comprise thinning the first packaging layer 410 to reduce the size of the packaging structure. The material of the first packaging layer 410 may comprise one or more of epoxy resin, and polyimide. After the first packaging layer 410 is formed, it may be thinned by Chemical Mechanical Polishing (CMP), to further reduce the size of the packaging structure.

The electrical connection of the low noise amplifier 303, the power amplifier 304, and the filter 305 to the second rewiring layer 120 may be protected by the first bottom filling layer 501, and the first bottom filling layer 501 is made of insulation materials.

Specifically, the line dimension of the SIP structure of the three-dimensional RF module can be 2 μm or less, such as 2 μm or 1.5 μm, etc. ; the line space dimension of the SIP structure of the three-dimensional RF module can be 2 μm or less, such 2 μm or 1.5 μm, etc. In one embodiment, various RF components can be integrated into a three-dimensional RF module SIP structure through the first rewiring layer 110, the second rewiring layer 120, and the metal columns 200, which can realize a high-performance systematic packaging, and can effectively reducing the packaging area and packaging volume.

As a preferred example, the RF switch 301 is provided with a shielding layer (not shown) on its surface, and the shielding layer is apart from the electrically conductive connectors of the RF switch. The shielding layer reduces the influence of electromagnetic waves generated during the operation of the RF switch on other components within the SIP structure of the three-dimensional RF module.

As an example, the SIP structure of the three-dimensional RF module may be a wafer-level three-dimensional RF module SIP structure to further provide production efficiency, wherein the corresponding wafer-level dimension may be one of 12 inches, 8 inches, and 6 inches.

### Embodiment 2

As shown in FIG. 2, Embodiment 2 provides a three-dimensional RF module SIP structure, which differs from Embodiment 1 mainly in that: the SIP structure of the three-dimensional RF module of Embodiment 2 further comprises a second packaging layer 420 located on the second surface of the second rewiring layer 120, covering the low noise amplifier 303, the power amplifier 304, the filter 305 and the first bottom filling layer 501.

Specifically, the method of forming the second packaging layer 420 may comprises one of compression molding, transfer molding, liquid seal molding, vacuum lamination, and spin-coating; the second packaging layer 420 may be thinned after forming to reduce the size of the packaging structure. The material of the second packaging layer 420 may comprises one or more of epoxy resin, and polyimide. After forming the second packaging layer 420, the second packaging layer 420 may be thinned by the CMP method, to further reduce the size of the packaging structure.

The structure and material of other components in the SIP structure of the three-dimensional RF module are detailed in Embodiment 1.

### Embodiment 3

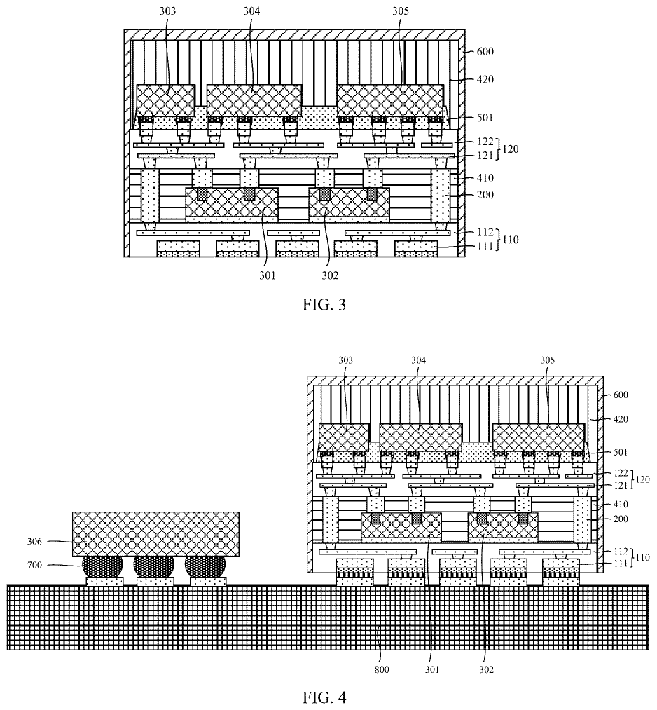

As shown in FIG. 3, Embodiment 3 provides a three-dimensional RF module SIP structure, which differs from Embodiment 2 mainly in that: the SIP structure of the three-dimensional RF module of Embodiment 3 further comprises an electromagnetic isolation protective housing 600 located at a periphery of the first packaging layer 410, the second packaging layer 420, the first rewiring layer 110 and the second rewiring layer 120 and partially exposing the second surface of the first rewiring layer 110.

The structure and material of other components in the SIP structure of the three-dimensional RF module are detailed in Embodiment 2.

### Embodiment 4

As shown in FIG. 4, Embodiment 4 provides a SIP structure of a three-dimensional RF module, which differs from Embodiment 3 mainly in that: the SIP structure of the three-dimensional RF module of Embodiment 4 further comprises a PCB substrate 800 and a transceiver 306; the transceiver 306 and an intermediate packaging structure comprising an intermediate electromagnetic isolation protective housing (not shown in FIG. 4) covering the transceiver 306 and metal bumps 700 over the PCB substrate 800, are electrically connected to the PCB substrate 800.

The structure and material of other components in the SIP structure of the three-dimensional RF module are detailed in Embodiment 3.

### Embodiment 5

As shown in FIG. 5, Embodiment 5 provides a three-dimensional RF module SIP structure, which differs from Embodiment 2 mainly in that: the SIP structure of the three-dimensional RF module of Embodiment 5 further comprises a transceiver 306 located on the second surface of the first rewiring layer 110 and electrically connected to the first rewiring layer 110, wherein a second bottom filling layer 502 is formed between the transceiver 306 and the first rewiring layer 110.

Specifically, the material of the second bottom filling layer 502 may be the same as or different from the first bottom filling layer 501, and the second bottom filling layer 502 serves to ensure the protection of the electrical connection between the transceiver 306 and the first rewiring layer 110. The use of an insulating material is imperative for the composition of the second bottom filling layer 502.

Furthermore, the metal bumps 700 located on the second surface of the first rewiring layer 110 are electrically connected to the first rewiring layer 110, and end portions of the metal bumps 700 protrudes from the surface of the transceiver 306.

Specifically, subsequent electrical lead-out may be facilitated by the metal bumps 700, and the metal bumps 700 may be tin balls prepared using a reflow soldering process.

The structure and material of other components in the SIP structure of the three-dimensional RF module are detailed in Embodiment 2.

### Embodiment 6

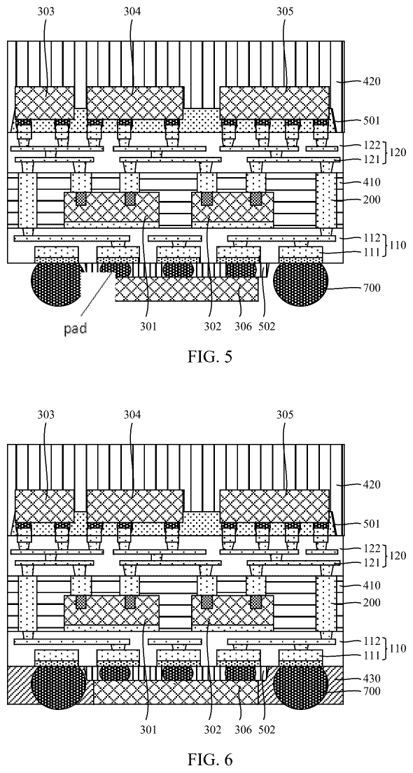

As shown in FIG. 6, Embodiment 6 provides a three-dimensional RF module SIP structure, which differs from Embodiment 5 mainly in that: the SIP structure of the three-dimensional RF module of Embodiment 6 further comprises a third packaging layer 430 covering the transceiver 306, the second bottom filling layer 502 and the metal bumps 700, wherein the first surface of the third packaging layer 430 is in contact with the second surface of the first rewiring layer 110, and the second surface of the third packaging layer 430 exposes the end portions of the metal bumps 700, thereby facilitating subsequent electrical connections through the metal bumps 700 that are exposed.

The structure and material of other components in the SIP structure of the three-dimensional RF module are detailed in Embodiment 5.

### Embodiment 7

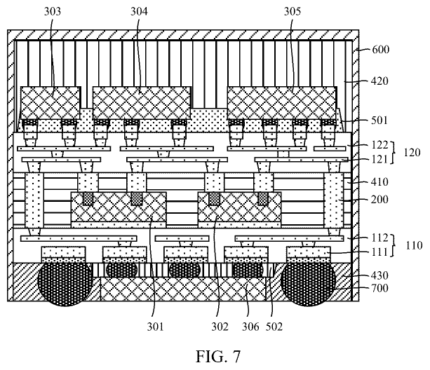

As shown in FIG. 7, Embodiment 7 provides a three-dimensional RF module SIP structure, which differs from Embodiment 5 mainly in that: the SIP structure of the three-dimensional RF module of Embodiment 7 further comprises an electromagnetic isolation protective housing 600, which exposes the second surface of the third packaging layer 430, and is located at a periphery of the first packaging layer 410, the second packaging layer 420, the third packaging layer 430, the first rewiring layer 110, and the second rewiring layer 120.

The structure and material of other components in the SIP structure of the three-dimensional RF module are detailed in Embodiment 6.

In summary, this present disclosure provides a three-dimensional RF module SIP structure, which integrates various RF components into a three-dimensional RF module SIP structure through the first rewiring layer, the second rewiring layer, and the metal columns, which can realize a high-performance systematic packaging, and the packaging line dimension and line space dimension can be up to 2 μm/2 μm, which can effectively reduce the packaging area and packaging volume.

The above-mentioned embodiments are merely illustrative of the principle and effects of the present disclosure instead of restricting the scope of the present disclosure. Those skilled in the art can make modifications or changes to the above-mentioned embodiments without going against the spirit and the range of the present disclosure. Therefore, all equivalent modifications or changes made by those who have common knowledge in the art without departing from the spirit and technical concept disclosed by the present disclosure shall be still covered by the claims of the present disclosure.

What is claimed is:

1. A System-In-a-Package (SIP) structure of three-dimensional Radio Frequency (RF) module, wherein the SIP structure of the three-dimensional RF module comprises:
a first rewiring layer, wherein the first rewiring layer comprises a first surface and a second surface opposite to the first surface;
metal columns, wherein the metal columns are located on the first surface of the first rewiring layer, and first end portions of the metal columns are electrically connected to the first rewiring layer;
an RF switch and a duplexer, wherein both the RF switch and the duplexer are located on the first surface of the first rewiring layer, and wherein electrically conductive connectors of both the RF switch and the duplexer are disposed away from the first rewiring layer;
a first packaging layer, wherein the first packaging layer is located on the first surface of the first rewiring layer, and where the first packaging layer covers the metal columns, the RF switch, and the duplexer, and where the first packaging layer exposes second end portions of the metal columns, and top surfaces of the electrically conductive connectors of both the RF switch and the duplexer;
a second rewiring layer, wherein the second rewiring layer is located on the first packaging layer and comprises a first surface in contact with the first packaging layer and a second surface opposite to its first surface, wherein the second rewiring layer is electrically connected to the second end portions of the metal columns, and the electrically conductive connectors of both the RF switch and the duplexer;
a low noise amplifier, a power amplifier, and a filter, wherein the low noise amplifier, the power amplifier and the filter are located on the second surface of the second rewiring layer, and wherein electrically conductive connectors of the low noise amplifier, the power amplifier and the filter are electrically connected to the second rewiring layer; and
a first bottom filling layer, wherein the first bottom filling layer is located on the second surface of the second rewiring layer and covers the electrically conductive connectors of the low noise amplifier, the power amplifier, and the filter.

2. The SIP structure of the three-dimensional RF module according to claim 1, further comprising a second packaging layer located on the second surface of the second rewiring layer, wherein the second packaging layer covers the low noise amplifier, the power amplifier, the filter and the first bottom filler layer.

3. The SIP structure of the three-dimensional RF module according to claim 1, further comprising a second packaging layer located on the second surface of the second rewiring layer, covering the low noise amplifier, the power amplifier, the filter and the first bottom filler layer.

4. The SIP structure of the three-dimensional RF module according to claim 3, further comprising a PCB substrate and a first transceiver, wherein the first transceiver and an intermediate packaging structure comprising an intermediate electromagnetic isolation protective housing are electrically connected to the PCB substrate.

5. The SIP structure of the three-dimensional RF module according to claim 2, further comprising a second transceiver located on the second surface of the first rewiring layer and electrically connected to the first rewiring layer, wherein a second bottom filling layer is formed between the second transceiver and the first rewiring layer.

6. The SIP structure of the three-dimensional RF module according to claim 5, further comprising metal bumps located on the second surface of the first rewiring layer, wherein the metal bumps are electrically connected to the first rewiring layer, and end portions of the metal bumps are configured to be further away from the first rewiring layer than a bottom surface of the second transceiver is from the first rewiring layer.

7. The SIP structure of the three-dimensional RF module according to claim 6, further comprising a third packaging layer covering the second transceiver, the second bottom filling layer and the metal bumps, wherein a first surface of the third packaging layer is in contact with the second surface of the first rewiring layer, wherein a second surface of the third packaging layer exposes the end portions of the metal bumps.

8. The SIP structure of the three-dimensional RF module according to claim 7, further comprising an electromagnetic isolation protective housing, which exposes the second surface of the third packaging layer, and is located at a periphery of the first packaging layer, the second packaging layer, the third packaging layer, the first rewiring layer, and the second rewiring layer.

9. The SIP structure of the three-dimensional RF module according to claim 1, wherein a line dimension of the SIP structure of the three-dimensional RF module is 2 μm or less, and a line space dimension of the SIP structure of the three-dimensional RF module is 2 μm or less.

10. The SIP structure of the three-dimensional RF module according to claim 1, wherein the SIP structure of the three-dimensional RF module is a wafer-level SIP structure of the three-dimensional RF module.
